(19) United States
(12) Patent Application Publication
(10) Pub. No.: US 2014/0184044 A1
(43) Pub. Date: Jul. 3, 2014

(54) CHASSIS FOR A COMPUTING DEVICE

(71) Applicant: PAUL GWIN, Orangevale, CA (US)

(72) Inventor: PAUL GWIN, Orangevale, CA (US)

(21) Appl. No.: 13/730,569

(22) Filed: Dec. 28, 2012

(51) Int. Cl. B29C 70/30; H05K 7/18; H05K 5/00

(52) U.S. Cl. CPC B29C 70/30; H05K 5/00; H05K 7/18
USPC 312/223.2; 156/245; 312/223.1

(57) ABSTRACT

A chassis for a computing device and a method for generating the chassis. The method includes generating a polymer-fiber sheet comprising composite strands of discontinuous fiber strands. Each of the discontinuous fiber strands overlap with a neighboring discontinuous fiber strand, and are impregnated with a polymer. The sheet is heated above the glass temperature of the polymer. The sheet is inserted into a mold. Additionally, the sheet is molded to a specified shape to generate the chassis. Further, the chassis is cooled below the glass temperature.

### TECHNICAL FIELD

The present embodiment relates generally to a chassis for a computing device. More specifically, the present embodiment relates to a computer chassis made from composite strands of discontinuous carbon fibers.

### BACKGROUND ART

Computers with lighter and stiffer computer cases, e.g., laptops , are increasingly popular consumer devices are designed to withstand wear and tear. The computer case may include a carbon fiber chassis, which can be coated by a polymer film. The carbon fiber chassis is made from a carbon fiber fabric that is impregnated with a thermoplastic polymer, called a “prepreg,” herein. The prepreg is then molded into the shape of the chassis. This approach is sufficient for producing relatively flat, two-dimensional shapes.

However, when molding more three-dimensional (3-D) shapes, the carbon fiber fabric may not be sufficiently flexible, causing wrinkles, non-uniform thickness, and other cosmetic defects. Typical approaches to this problem involve using carbon fibers in a plain weave, or twill weave, in the carbon fiber fabric. These weaves are more conforming than non-weave carbon fiber fabrics, but are still limited in their ability to conform to 3-D shapes, such as a ball, or an egg, without causing the prepreg to wrinkle.

These constraints limit the design possibilities for the various kinds of computer cases that can be molded using a prepreg. In the competitive field of consumer electronics, for example, designs may be the deciding factor for many customers. Thus, design limitations that limit consumer choice may result in decreased sales. Further, limits in possible designs may limit the ways that consumers can enjoy and use their various computing devices.

### BRIEF DESCRIPTION OF THE DRAWINGS

FIG. 1 is a block diagram of a system for generating a computer chassis in accordance with embodiments;

FIGS. 2A, 2B are block diagrams of a composite strand, in accordance with embodiments;

FIGS. 3A and 3B are block diagrams of systems for generating the CF prepreg 102; and

FIG. 4 is a process flow diagram showing a method for manufacturing a computer chassis in accordance with embodiments.

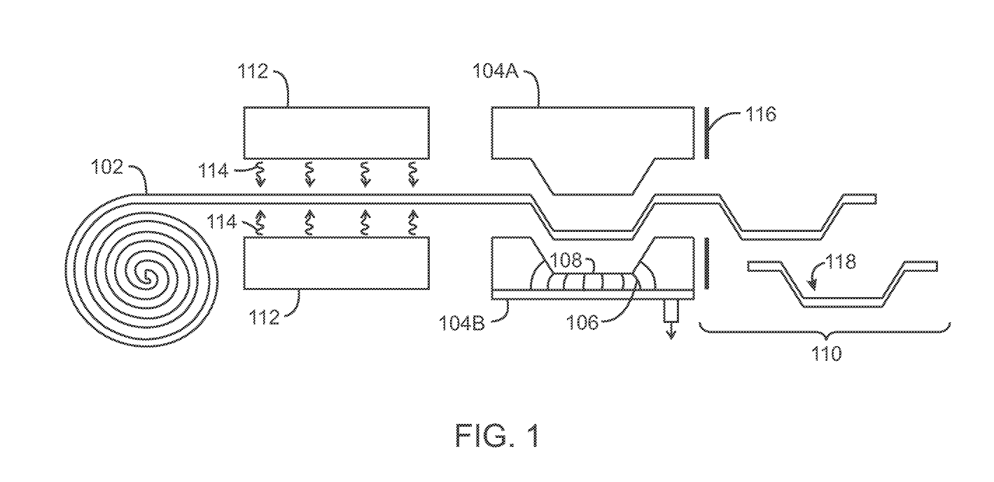

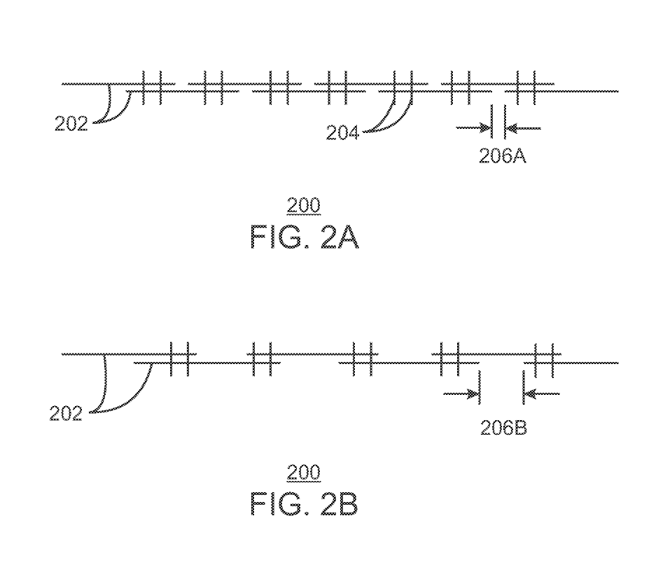

The same numbers are used throughout the disclosure and the figures to reference like components and features. Numbers in the 100 series refer to features originally found in FIG. 1; numbers in the 200 series refer to features originally found in FIG. 2; and so on.

### DESCRIPTION OF THE EMBODIMENTS

In the following description and claims, an embodiment is an implementation or example. Reference in the specification to “an embodiment,” “one embodiment,” “some embodiments,” “various embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. Elements or aspects from an embodiment can be combined with elements or aspects of another embodiment.

Not all components, features, structures, characteristics, etc. described and illustrated herein need be included in a particular embodiment or embodiments. If the specification states a component, feature, structure, or characteristic “may”, “might”, “can” or “could” be included, for example, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

It is to be noted that, although some embodiments have been described in reference to particular implementations, other implementations are possible according to some embodiments. Additionally, the arrangement or order of features illustrated in the drawings or described herein need not be arranged in the particular way illustrated and described. Many other arrangements are possible according to some embodiments.

In each figure, elements may each have a same reference number or a different reference number to suggest that the elements represented could be different or similar. However, an element may be flexible enough to have different implementations and work with some or all of the systems shown or described herein. The various elements shown in the figures may be the same or different. Which one is referred to as a first element and which is called a second element is arbitrary.

In one embodiment, a polymer impregnated fabric, or prepreg, is generated from composite strands of fibers, such as carbon fibers or glass fibers, among others. A composite strand includes shorter strands of discontinuous fibers that are stitched together, banded together, woven, or held together into a strand using a thermoplastic binder. These composite strands, unlike individual continuous fiber strands, may stretch and contract during forming operations. Thus, a fiber cloth made from composite strands may conform to three-dimensional shapes without wrinkling or causing other cosmetic defects.

Light, resilient cases for computing devices typically include a fiber reinforced polymer chassis that may be covered with various cosmetic or protective films. The chassis may be generated using one of various forming techniques. Although a thermoplastic is generally discussed herein, the polymer is not limited to thermoplastic polymers, but may also include thermoset polymers. For example, if the prepreg is formed using a thermoset polymer, the prepreg may be molded to form the desired shape, and then held in the mold while being heated to cause cross-linking in the polymer. The cross-linking fixes the shape of the polymer, allowing the mold to be cooled and the part removed.

If a thermoplastic is used, the chassis may be formed using compression molding, derivations of compression molding, resin transfer molding, thermoforming techniques, and so on. Compression molding is the process of forming a polymer chassis by compressing the polymer fiber and films between two matched metal dies. The compression generates pressure within the mold cavity, forcing the polymer matrix into the shape of the chassis mold.

Thermoforming is the process of forming a polymer chassis through the use of heat and metal dies. Any thermoplastic resin that can be processed into a sheet can also be thermoformed. However, if the heat exceeds the hot strength capabilities, the polymer material loses the ability to support itself. Thermoforming techniques include, but are not limited to, vacuum, drape, pressure, and matched-mold thermoforming.

FIG. 1 is a block diagram of a system 100 for generating a computer chassis in accordance with embodiments. The system 100 includes a polymer-fabric sheet (CF prepreg) 102, mold top 104A, and mold bottom 104B. The mold bottom 104B includes fine vacuum ports 106 for air evacuation from a surface 108. The system 100 also includes one or more downstream stations 110 for post-molding processes, such as cooling, cutting, or molding other features, such as bosses.

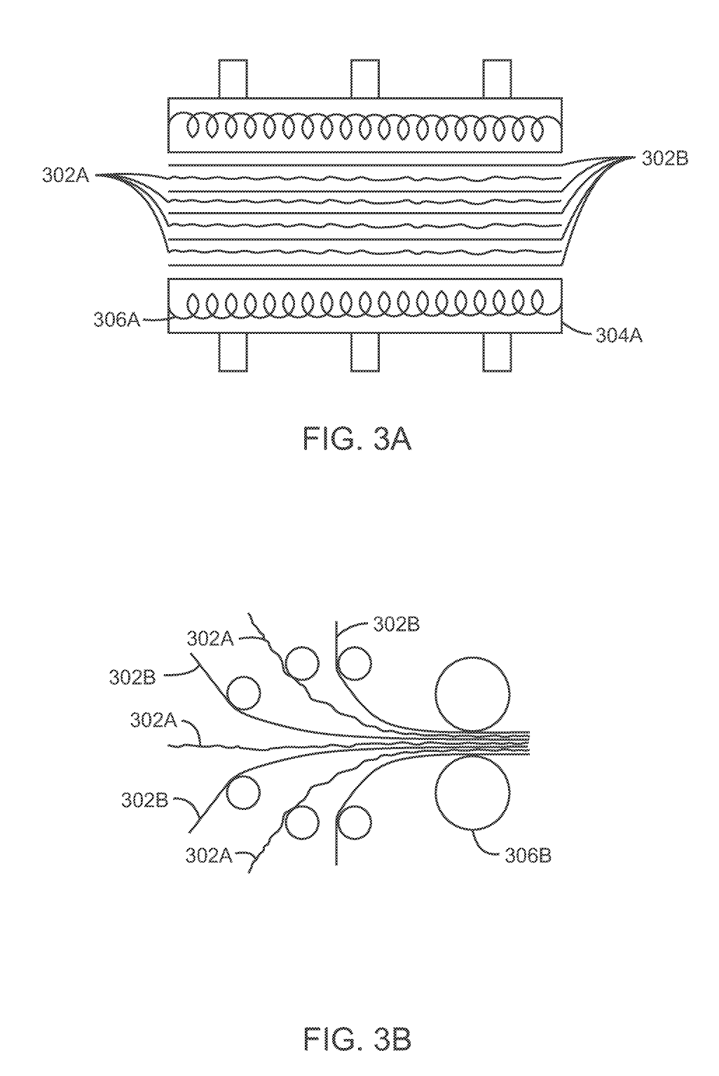

The CF prepreg 102 includes a fabric mat that is embedded in a layer of polymer. The specified polymer holds the mat together and contributes useful properties, such as tensile strength and elastic modulus. Tensile strength represents the maximum amount of tensile stress that a material can take without breaking. The elastic modulus represents the elasticity, or alternatively, stiffness, of the material. The CF prepreg 102 is described in greater detail with respect to FIGS. 3A and 3B.

Heat trays 112 radiate infrared energy 114, heating the CF prepreg 102 beyond a softening point, termed the glass transition temperature. The heated CF prepreg 102 is then placed between the mold top 104A and the mold bottom 104B. The mold is closed on the sheet, and a vacuum is pulled through the vacuum ports 106 to conform the prepreg 102 to the mold, for example, the mold bottom 104B. At a downstream station, a cutting tool 116 can be used to cut the formed chassis 118 from the CF prepreg 102.

FIGS. 2A, 2B are block diagrams of a composite strand 200, in accordance with embodiments. The composite strand 200 includes discontinuous fiber strands 202, disposed coaxially and overlapping with each other. The discontinuous strands 202 may be held in contact with each other by bands 204 or by other techniques, such as thermoplastics. Multiple composite strands 200 can be woven together to make a fabric by individually securing a hoop of fiber around the coaxial assembly, by wrapping a fiber helically around the coaxial assembly, by stitching across a sheet of coaxiable fibers not yet connected, and so on. When the fabric is molded into a die with a three dimensional (3D) shape, such as a deeply recessed chassis, some composite strands 200 stretch, e.g., by allowing the discontinuous strands to slide relative to each other, to allow the fabric to conform without wrinkling.

FIG. 2B shows the composite strand 200 in a stretched state. In the stretched state, a gap 206B is shown. Referring back to FIG. 2A, which shows gap 206A before stretching of the composite strand 200. The composite strand 200 has the ability to stretch because of the overlapping discontinuous strands 202. As a tension is applied, the discontinuous strands 202 elongate in the direction of the tension.

The stretching occurs during the molding operation while the polymer is above the glass transition temperature, i.e., still in viscous form. As shown, the discontinuous strands 202 slide axially, remaining proximate to adjacent strands. When the polymer cools, the discontinuous strands are held together by the cooled polymer matrix. Because there is sufficient overlap of the proximately located strands, the physical properties are high in comparison to a typical discontinuous fiber system. A typical continuous fiber system can achieve approximately 10 MSI elastic modulus in the fill and warp directions of the fabric reinforced polymer composite. However, discontinuous coaxial aligned fibers can achieve approximately 90% of continuous fiber system values in tension and parity on shear. Randomly oriented fibers may be only 10-20% of the continuous values.

FIGS. 3A and 3B are block diagrams of systems 300A, 300B for generating the CF prepreg 102. In system 300A, the structure of the mat for the CF prepreg is formed by laying fabric strips 302A between thermoplastic sheets 302B to form the final structure. A hydraulic press 304A, containing a heating coil 306A, may heat the stacks fabric 302A and polymer sheet prepreg strips beyond the glass transition temperature. While the polymer is still in viscous form, the hydraulic press 304A compresses the prepreg strips into a polymer fiber mat, e.g., CF pregpreg 102.

These prepreg strips 302A are made from composite strands of fiber. The pre-impregnated fiber may be made from at least one of carbon fibers, aramid fibers, glass fibers, other synthetic or organic fibers, or a combination of two or more fibers. The composite strands may be woven or unwoven. Woven fabrics may include, but are not limited to, plain, twill, satin, and basket. Alternatively, weaves may be specific to the material, e.g., a carbon fiber weave. To form the prepreg, the fabric may be impregnated with thermoplastic resins such as Nylon, polyphenylene sulfide (PPS), acrylonitrile-butadiene-styrene (ABS), polycarbonate (PC), poly-ether-ether-ketone (PEEK), other thermoplastic resins, blends, or composites thereof. Alternatively, a thermoset may be used, as described herein. Thermoset resins may include epoxies, acrylates, and other resins that may be thermally or chemically cross-linked.

In system 300B, composite strands 302B of a specified fiber are fed in tandem with a thermoplastic film 304B of the specified polymer. These are fed into heated rollers, which embed the composite strands 302B in the specified polymer to generate the polymer fabric mat.

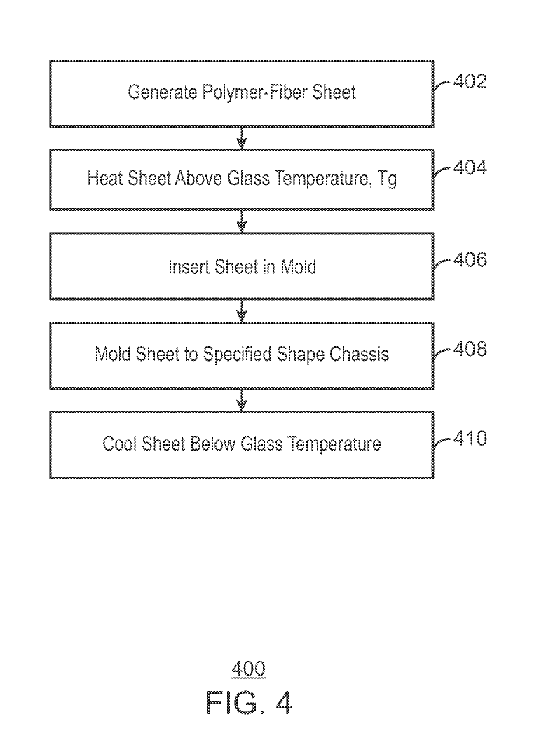

FIG. 4 is a process flow diagram 400 showing a method for manufacturing a chassis for a computing device in accordance with embodiments. At block 402, a polymer-fiber sheet, e.g., CF prepreg 102, is generated. The polymer-fiber sheet may be cut to size before molding, or may be continuously provided from a roll of the fabric reinforced polymer composite.

At block 404, the polymer-fiber sheet is heated above the glass transition temperature of the sheet's polymer, Tg. The heat may be provided by a radiation oven, convection oven, or contact with a heated platen. In one embodiment, the heated CF prepreg 102 is pre-stretched to control the thickness. At block 406, polymer-fiber sheet is placed in a matched metal die, e.g., mold top 104A and mold bottom 1048, as described with respect to FIG. 1. It is noted that other mold arrangements are possible, and not limited to those described with respect to FIG. 1.

At block 408, the polymer-fiber sheet is molded into the specific shape of the chassis. At block 410, the formed chassis is cooled to below Tg, and die cut from its sheet. In one embodiment, the formed chassis is trimmed using dies in the mold or at a downstream station 110.

It is to be understood that specifics in the aforementioned examples may be used anywhere in one or more embodiments. For instance, all optional features of the computing device described above may also be implemented with respect to either of the methods or the computer-readable medium described herein. Furthermore, although flow diagrams may have been used herein to describe embodiments, such embodiments are not limited to those diagrams or to corresponding descriptions herein. For example, flow need not move through each illustrated box or state or in exactly the same order as illustrated and described herein.

The embodiments are not restricted to the particular details listed herein. Indeed, those skilled in the art having the benefit of this disclosure will appreciate that many other variations from the foregoing description and drawings may be made within the scope of the present embodiments. Accordingly, it is the following claims including any amendments thereto that define the scope of the embodiments.

What is claimed is:

1. A method for generating a chassis for a computing device, comprising:
generating a sheet comprising composite strands of discontinuous fiber strands impregnated with a polymer, wherein each of the discontinuous fiber strands overlap with a neighboring discontinuous fiber strand;
heating the sheet above a glass temperature of the specific polymer;
inserting the sheet in a mold;
molding the sheet to a specified shape to generate the chassis; and
cooling the chassis below the glass temperature.

2. The method of claim 1, comprising maintaining contact between overlapping fiber strands.

3. The method of claim 2, wherein the overlapping fiber strands are woven together in order to maintain contact with each other.

4. The method of claim 2, wherein the overlapping fiber strands are banded together in order to maintain contact with each other.

5. The method of claim 4, wherein a carbon fiber band bands together the overlapping fiber strands.

6. The method of claim 1, wherein the overlapping fiber strands are disposed coaxially to each other.

7. The method of claim 1, wherein the discontinuous fiber strands comprise carbon fibers.

8. The method of claim 1, comprising stretching the composite sheet while the polymer is above the glass temperature.

9. The method of claim 8, wherein stretching the composite strands comprises moving discontinuous fiber strands while maintaining proximity to overlapping fiber strands.

10. The method of claim 1, wherein generating the chassis comprises one of:
vacuum thermoforming the sheet into a 3-dimensional shape;
compression molding the sheet into a 3-dimensional shape; and
resin transfer molding the sheet into a 3-dimensional shape.

11. A chassis for a computing device, comprising:
a polymer;
a plurality of composite strands, comprising a plurality of discontinuous fiber strands that are embedded in the polymer, wherein each of the discontinuous fiber strands overlap with a neighboring discontinuous fiber strand; and
a three-dimensional shape.

12. A computer case, comprising:
A chassis for a computing device, comprising:
a polymer;
a plurality of composite strands, comprising a plurality of discontinuous fiber strands that are embedded in the polymer, wherein each of the discontinuous fiber strands overlap with a neighboring discontinuous fiber strand;
a three-dimensional shape; and
a polymer film covering the chassis.

13. The computer case of claim 12, wherein the discontinuous fiber strands are banded together with the neighboring discontinuous fiber strand.

14. An electronic device case comprising a chassis, the chassis comprising:
a polymer;
a plurality of composite strands, comprising a plurality of discontinuous fiber strands that are embedded in the polymer, wherein each of the discontinuous fiber strands overlap with a neighboring discontinuous fiber strand, wherein the discontinuous fiber strands are banded together with the neighboring discontinuous fiber strand;
a three-dimensional shape; and
a polymer film covering the chassis.

15. The electronic device case of claim 14, wherein the electronic device comprises a smartphone, and wherein the three-dimensional shape comprises an egg shape.

16. A method for generating a polymer-fiber mat, comprising:
laying a plurality of fabric strips between a plurality of thermoplastic sheets comprising a polymer, to generate a structure of a polymer fiber mat, wherein the fabric strips comprise discontinuous fiber strands banded together, such that each of the discontinuous fiber strands overlaps a neighboring discontinuous fiber strand;
heating the structure beyond a glass transition temperature of the polymer;
compressing the fabric strips into the polymer until each of the prepreg strips is embedded in a layer of the polymer, to generate the polymer fiber mat.

17. The method of claim 16, comprising cooling the polymer fiber mat.

18. The method of claim 16, comprising trimming the polymer fiber mat.

19. The method of claim 16, wherein the discontinuous fiber strands comprise carbon fiber

20. The method of claim 16, wherein compressing the fabric strips into the polymer is performed by a hydraulic press.

21. The method of claim 16, wherein compressing the fabric strips into the polymer is performed by a pair of heated rollers.

22. The method of claim 16, comprising:
cooling the polymer fiber mat; and
cutting the polymer fiber mat.
